(19) United States
(12) Patent Application Publication
(10) Pub. No.: US 2011/0169517 A1
(43) Pub. Date: Jul. 14, 2011

(54) MEMS PROBE CARD AND METHOD OF MANUFACTURING SAME

(76) Inventors: Sang-Hee Kim, Seoul (KR); Sang Hyun Lee, Daegu (KR); Jae Seok Lee, Gyeonggi-do (KR); Chun Sik Woo, Gyeongsangbuk-do (KR); Jae In Lee, Gyeongsangbuk-do (KR)

(21) Appl. No.: 13/062,340

(22) PCT Filed: Jun. 19, 2009
(86) PCT No.: PCT/KR2009/003306

§ 371 Date: Apr. 1, 2011

(30) Foreign Application Priority Data
Sep. 5, 2008 (KR) 10-2008-0087787
Sep. 9, 2008 (KR) 10-2008-0088856
Dec. 1, 2008 (KR) 10-2008-0120450

(51) Int. Cl. G01R 31/00

(52) U.S. Cl. 324/756.03

(57) ABSTRACT

Provided are a micro-electro-mechanical system (MEMS) probe card and a method for manufacturing thereof. The MEMS probe card includes a substrate provide with a via hole filler conductor or a via hole filled with the resistor, the resistive film formed on the via hole and the substrate, the insulating film and the resistive film formed on the resistive film and the substrate, and the electrode formed on the substrate to cover the insulating film

As such, by means of a micro-electro-mechanical system (MEMS) probe card and a method for manufacturing thereof, the precise resistance value can be obtained and used for the semiconductor IC and others in the event of significant change in power.

### BACKGROUND OF THE INVENTION

1. Field of the Invention

The present invention relates to a micro-electro-mechanical system (MEMS) probe card of high chemical resistance and a method for manufacturing thereof, and more particularly, to a MEMS probe card and a method for manufacturing thereof, in which a stable resistance ratio can be obtained, and the MEMS probe card can be used in the event of significant change in power, and a precise resistive conductive line can be formed

2. Description of Related Art

In general, a probe card used in a test device for semiconductor IC and such is a device including a predetermined substrate and probes arranged on the substrate. The probe card is used to test electrical characteristics of micro electronic device such as semiconductor device.

The semiconductor device includes pads on its surface to transmit and receive signals to and from an external electronic device. That is, the semiconductor device receives an electrical signal from the external electronic device through the pads, performs a predetermined operation, and transmits the result to the external electronic device through the pads.

In this case, the probe card forms an electrical path between the semiconductor device and the external electronic device (e.g., test device), thereby enabling an electrical test of the semiconductor device

Meanwhile, as semiconductor device are becoming highly integrated, the pads of the semiconductor device are being micronized and the distance between the pads is being reduced. Thus, it is necessary to downsize the probe card according to the high integration of semiconductor device. However, the necessity for downsizing the probe card complicates the manufacture of the probe card.

With the upsizing of substrates and the necessity for high-speed processing due to the development of semiconductor technology, a micro-electro-mechanical system (MEMS) probe card to which a microprobe using a semiconductor MEMS technique is used is applied instead of an existing pin type probe card as the test device for semiconductor IC.

Meanwhile, a multichannel probe is required due to an increase in the number of I/O pins of the semiconductor IC. However, even when only one channel is short-circuited in the multichannel probe, an excessive current flows through the corresponding channel, which may cause a spark-induced failure at probe terminals. Thus, it is necessary to devise a plan to solve the problem.

As a part of the plan, there has recently been proposed a technique for preventing excessive current from flowing through probe terminals by connecting the probe terminals with a resistive conductive line.

FIG. 1 is a cross-sectional view showing a structure of a resistive conductive line for a conventional MEMS probe card.

As shown in FIG. 1, the conventional MEMS probe card has a structure in which a conductive line 10 is formed on the surface of a high-temperature co-fired ceramic (HTCC) substrate, a via hole formed in the conductive line 10 is filled with a via filler conductor 11, and a thin film resistor 12 and a thin film conductive line 13 for a MEMS probe are formed on the surface of the conductive line 10.

A resistive conductive line is formed by the via filler conductor 11, the thin film resistor 12, and the thin film conductive line 13, and the current is controlled by the resistive conductive line.

Reference numeral 14 denotes a bump pad, reference numeral 15 denotes an adhesive agent, reference numeral 16 denotes a MEMS probe, and reference numeral 17 denotes a probe tip.

In the conventional thin film resistor substrate, however, it is difficult to apply the thin film resistor 12 to the MEMS probe card which requires high electric power by the increase of I/O pins of semiconductor IC when the thin film resistor 12 is designed to have a width equal to or smaller than that of the electrode 13.

In the structure as shown in FIG. 1, there has also been the problem that the pattern stability becomes lowered due to the small contact area between the resistive film 12 and the electrode 13.

In addition, in the conventional thin film resistor substrate, there is the problem that it is difficult to form a plurality of resistive film 12 against the increase of I/O pins of semiconductor IC and the probe tip; that is, the problem that it is difficult to form a plurality of resistive film having the desirable resistance value within the predetermined space.

In the structure as shown in FIG. 1, there has also been the problem that the protection layer should be formed on the resistive film 12 and the electrode 13

Furthermore, since the thin film resistor 12 is connected to the thin film conductive line 13 of the conventional MEMS probe card in series in an X or Y direction, the circuit integration is lowered, and this problem becomes more serious when the thin film resistor 12 is designed in the form of a bar.

Meanwhile, the HTCC substrate is heat-treated at a temperature of 1,500° C. or more to form a multilayer wiring substrate. As insulating materials of the HTCC substrate, more than 94% alumina is used as a main material, and a small amount of silica is used as an additive. The electrical conductor is mainly formed of tungsten (W), which can be fired at a high temperature. Since the HTCC substrate has excellent mechanical strength and chemical resistance, it is widely applied in highly integrated packaging by forming the thin film conductive line on the surface of the HTCC substrate.

However, since the tungsten conductor fired at a high temperature has an electrical conductivity lower than that of silver (Ag) or copper (Cu), it has inferior high frequency characteristics. Moreover, since the thermal expansion coefficient of the tungsten conductive line is more than two times as high as a silicon semiconductor device, it is a serious problem in the field of application where matching of thermal expansion coefficients is required.

Meanwhile, a low-temperature co-fired ceramic (LTCC) substrate is occasionally used instead of the HTCC substrate. In this case, the LTCC substrate is heat-treated at a temperature of 1,000° C. or less to form a multilayer wiring substrate. In manufacturing the LTCC multilayer substrate, silica, which has a low melting point, is widely used to perform the heat treatment at a low temperature of 1,000° C. or less, and a relatively small amount of alumina is used. Moreover, since the firing temperature is 1,000° C. or less in the LTCC multilayer substrate, silver (Ag) or copper (Cu) having excellent electrical conductivity is used as an electrical conductor material.

However, despite the above advantages, the LTCC multilayer substrate has a rough surface, and thus it is difficult to form a thin film resistor having a thickness of several tens to several hundreds of nanometers (nm) on the surface of the LTCC multilayer substrate.

### SUMMARY OF THE INVENTION

The present invention is directed to a MEMS probe card to solve the conventional problems, which can cope with the significant change in power and set up the resistance value into the desirable level.

The present invention is also directed to a MEMS probe card and a method for manufacturing there of, in which the stability of contact pattern between resistive film and electrode can be kept by making the contact area big.

The present invention is also directed to a MEMS probe card and a method for manufacturing thereof, in which the stable resistance ratio can be obtained within the space at a narrow substrate from forming the second conductive line after coating the insulation layer, and the probe card can be stably used in the event of a significant change in power.

The present invention is also directed to a MEMS probe card and a method for manufacturing thereof, in which the ratio of resistance value can be easily controlled.

The present invention is also directed to a MEMS probe card and a method for manufacturing thereof, in which the pattern of thin film resistor and thin film conductive line is accurate and precise resistance value can be obtained.

The present invention provides a micro-electro-mechanical system (MEMS) probe card including: a substrate having a via hole filled with a via hole filler conductor or a resistor;

a resistive film formed on the via hole and the substrate;

an insulating film formed on the resistive film and the substrate; and

an electrode formed on the substrate to cover the resistive film and the insulating film.

The resistive film is rectangular-shaped and formed with the first resistive part stacked in the part of via hole and the second resistive part stacked on the substrate; and the insulating film is formed to be circular-shaped.

The end of the first resistive part is formed to be semicircular or circular arc-shaped.

The resistive film includes further, the third resistive part in series with the second resistive part.

The third resistive part is formed to be annular-shaped.

The first and the second resistive parts, or the first, the second and the third resistive parts are formed with one body; each width being the same.

The resistive film and the insulating film form the multi-layers alternately stacked respectively

The present invention provides a method for manufacturing a micro-electro-mechanical system (MEMS) probe card, the method comprising the steps of:

preparing the substrate filled with a via hole filler conductor or a resistor;

forming a resistive film in the via hole and on the substrate;

forming an insulating film on the resistive film and the substrate; and

forming an electrode on the substrate to cover the resistive film and the insulating film.

The resistive film and the insulating film form the multi-layers alternately stacked respectively

The present invention provides the MEMS probe card, comprising:

a substrate with a via hole filled with via hole filler conductor or resistor;

a thin film resistive line formed on the surface of the substrate;

the first first-conductive line formed on the surface of the substrate including the surface of the via hole filler conductor, and the second first-conductive line formed on the surface of the substrate facing to the first first-conductive line with the thin film resistive line being between the first first-conductive line and the second first-conductive line;

the insulating layers formed on the substrate, the thin film resistive line and the first and the second first-conductive lines;

the second conductive line formed on the insulating layer and the second first-conductive line exposed out of the insulating layer; and a bump pad and a probe tip fixing onto the second conductive line.

An electrode for bump pad in a same pattern with the second conductive line on the second conductive line, is formed.

The present invention provides a method for manufacturing a micro-electro-mechanical system (MEMS) probe card, the method comprising the steps of:

preparing the substrate having a via hole filled with a via hole filler conductor or a resistor;

forming a thin film resistive line on the surface of the substrate;

forming the first first-conductive line on the surface of the substrate including the surface of the via hole filler conductor, and the second first-conductive line formed on the surface of the substrate facing to the first first-conductive line with the thin film resistive line being between the first first-conductive line and the second first-conductive line;

form a insulating layers on the substrate, the thin film resistive line and the first and the second first-conductive lines;

form a second conductive line on the insulating layer and the second first-conductive line exposed out of the insulating layer; and a bump pad and a probe tip fixing onto the second conductive line.

The method includes further the step of forming an electrode for bump pad in a same pattern with the second conductive line on the second conductive line.

The present invention provides the a micro-electro-mechanical system (MEMS) probe card, comprising:

a low-temperature co-fired ceramic (LTCC) multilayer substrate formed by stacking the first to nth substrates and firing the stacked substrates at a temperature of 1,000° C. or less;

the upper conductive line formed with via hole filled with via hole filler conductor, and formed on the LTCC substrate;

the thin film resistor formed on the upper conductive line;

the first thin film conductive line formed on the via hole filler conductor, the upper conductive line and the thin film resistor; and

the insulating film formed on the thin film resistor and the first thin film conductive line.

The probe card includes further the second thin film conductive line formed on the upper conductive line, the thin film resistor and the thin insulating film.

One of the via holes formed at the first to nth layers is filled with the thick film resistor.

The via hole filler conductor consists of a metal selected from Ag, Pd, and Pt.

The insulating layer consists of Al₂O₃ or TiO₂.

The first and the second thin film conductive line consist of a mixed metal of Ti, Pd, Cu, or Al, Cu, Au.

The present invention provides a method for manufacturing a micro-electro-mechanical system (MEMS) probe card, the method comprising the steps of

preparing a low-temperature co-fired ceramic (LTCC) multilayer substrate by stacking the first to nth substrates and firing the stacked substrates at a temperature of 1,000° C. or less;

forming the upper conductive line having a via hole on the LTTC multilayer substrate;

filling the via hole with the via hole filler conductor;

forming the thin film resistor on the upper conductive line;

forming the first thin film conductive line on the upper conductive line, thin film resistor and the via hole filler conductor; and

forming the insulating film on the thin film resistor and the first thin film conductive line

The method includes further step of forming the second thin film conductive line on the upper conductive line, the thin film resistor and the insulating film after the step of forming the insulating film on the thin film resistor and the first thin film conductive line.

Any one of the via holes formed on the first to nth substrates is filled with the thick film resistive layer at the step of preparing a low-temperature co-fired ceramic (LTCC) multilayer substrate by stacking the first to nth substrates and firing the stacked substrates at a temperature of 1,000° C. or less

The insulating layer is formed by a process selected from ion-assisted physical vapor deposition (PVD) having a high film deposition rate, PVD as e-beam evaporation, pulsed laser deposition (PLD), and aerosol deposition.

### BRIEF DESCRIPTION OF THE DRAWINGS

FIG. 1 is a cross-sectional view showing a part of structure of a conventional MEMS probe card;

FIGS. 2a and 2b is a cross-sectional view and pattern illustration in accordance with a first exemplary embodiment of the present invention;

FIGS. 3a to 3c are diagrams showing the variation patterns of resistor in accordance with a first exemplary embodiment of the present invention;

FIG. 4 is a diagram showing the stacking pattern in accordance with a first exemplary embodiment of the present invention;

FIGS. 5a to 5c are the cross-sectional views showing the process for manufacturing a MEMS probe card in accordance with a first exemplary embodiment of the present invention;

FIG. 6 is a diagram showing the flow of process for manufacturing a MEMS probe card in accordance with a second exemplary embodiment of the present invention;

FIGS. 7 to 15 are diagrams illustrating the individual manufacturing process shown in FIG. 10

FIG. 16 is a cross-sectional view of a MEMS probe card in accordance with a third exemplary embodiment of the present invention;

FIG. 17 is a diagram showing manufacturing process of a MEMS probe card shown in FIG. 16.

FIG. 18 to 22 are the individual manufacturing process shown in FIG. 17.

### DETAILED DESCRIPTION OF THE INVENTION

Hereinafter, exemplary embodiments of the present invention will be described in detail with reference to the accompanying drawings.

### First Exemplary Embodiment

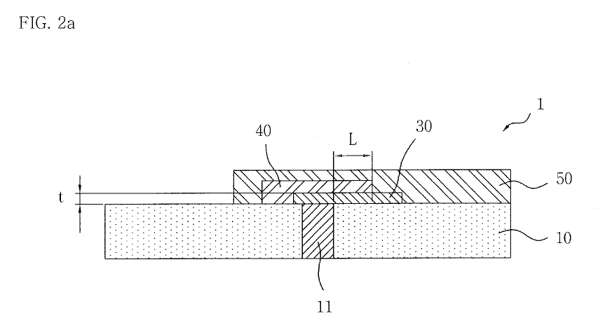

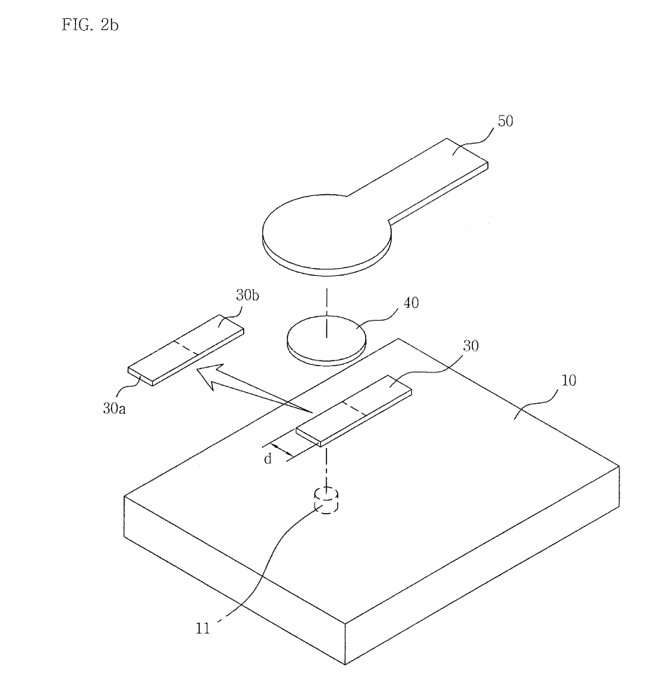

FIG. 2a and 2b are a cross sectional view of a thin film resistor substrate and illustration of the pattern in accordance with a first exemplary embodiment of the present invention.

First, the concept of a thin film resistor substrate by using an insulating film in accordance with a first exemplary embodiment of the present invention, will be described.

In the thin film resistor substrate, the decisive variables of resistance value(R) are k, the specific resistance value of a resistive film; t, the thickness of a resistive film and L, the length of a resistive film (the length of the duplicated part of the resistive film and an insulating film excluding the via hole, in FIG. 2); and d, the width of the resistive film.

Accordingly, the resistance value, as the following formula, is in proportion to the specific resistance value and length of material, and in inverse proportion to thickness and width.

R∝k(L/A) <formula 1>

The passage area of resistance, A=t*d.

As a dimensional analysis of A, the passage area of resistance, for example, when taking t=10⁻⁹, d=10⁻⁴, d(=10⁻⁴)>>t(=10⁻⁹), therefore, t as the thickness of resistive film may be trivial.

Accordingly, to make the formula again, it can be defined as resistance, (R)∝k(L/d).

The inventors of this present invention could find that a desirable resistance value can be obtained from a proper design of L and d of the resistive film through the process above.

The desirable resistance value can be obtained by making the length of resistive film long or making the width of resistive film narrow, however, it reaches the limits in controlling the length and width of resistive film on the substrate by miniaturization of the thin film resistance substrate and the stability of contact pattern between resistive film and electrode.

The first exemplary embodiment of the present invention diversifies the pattern of resistive film and proposes the stack-structured resistive film.

As shown in FIGS. 2a and 2b, the thin film substrate 1 according to the first exemplary embodiment of the present invention, comprises the substrate 10 having a via hole 11 filled with via hole filler conductor or resistor; a resistive film 30 on the via hole 11 and the substrate 10; an insulating film 40 formed on the resistive film 30 and the substrate 10; and an electrode 50 formed on the substrate 10, the resistive film 30 and the insulating film 40. That is, the resistive film 30, as shown in FIG. 2b, is approximately rectangular-shaped and is formed with via hole filler conductor filled in via hole 11, or with the first resistive part 30a stacked to cover the whole surface of resistor and the second resistive part 30b stacked on the substrate 10.

The insulating film 40 is stacked on the first resistive part 30a of the resistive film 30 and the substrate 10, and is formed to be approximately circular-shaped.

The electrode 50 is stacked on the substrate 10, being stacked to cover the whole of the resistive film 30 and the insulating film 40.

Preferably, the resistive film 30 consists of TaN, and the insulating film 40 consists of a high-k dielectric material selected from Al₂O₃, HfO₂, TiO₂, ZrO₂, Y₂O₃, Ta₂O₅, and La₂O₃, however, it may be desirable to include Al₂O₃ in view of the cost.

Preferably, the electrode 50 consists of a mixed metal of Ti/Pd/Cu, Ti/Cu, Ti/W/Cu, Al/Cu or Au.

The via filler conductor may consist of a metal selected from Ag, Pd, and Pt., however, it is desirable to consist of Pd or Pt when considering the conductivity.

However, the materials of the resistive film 30, the insulating film 40, the electrode 50, and the via filler conductor are not limited to the description above, they can be substituted with those having identical or similar properties.

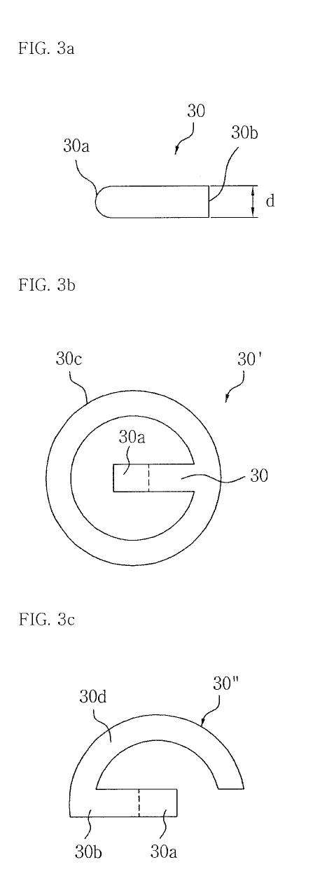

Next, exemplary embodiment of varied pattern of the resistive film to raise the resistance value, will be described in accordance with the FIGS. 3a to 3c.

The resistive film 30, as shown in FIG. 3, may form the end of first resistive part 30a to be semicircular or circular arc-shaped to secure the contact pattern of the resistive film 30 and the insulating film 40.

As shown in FIG. 3b, the third resistive part 30c in series with the second resistive part 30b and formed to be annular-shaped, may be prepared to keep d, the width of the resistive film 30 regularly and secure L, the length of the resistive film 30.

As shown in FIG. 3c, the third resistive part 30d in series with the second resistive part 30b and formed to be semi-annular-shaped may be prepared.

The resistive films 30′, 30″ in FIGS. 3b and 3c, can get the advantage of securing the stability of pattern by the increase of contact area between the resistive films 30″, 30″ and the electrode 50.

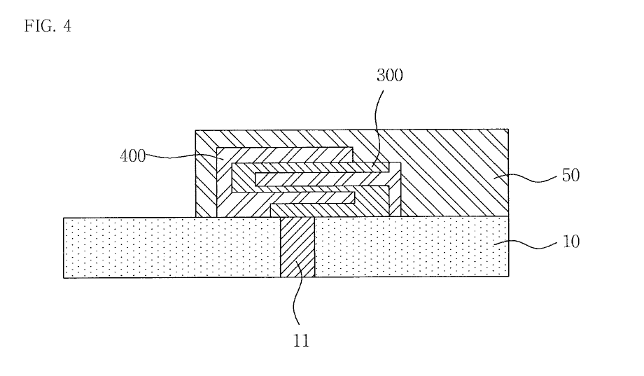

Another exemplary embodiment of varied pattern of the resistive film to raise the resistance value, will be described in accordance with the FIG. 4.

In the structure shown in FIG. 4, three layers of the resistive film 300 and the insulating film 400 are stacked alternately, however, this type of stacking structure is not limited to the three layers and any layers may be prepared according to the thickness of the individual film.

In case of forming the resistive film 300 to be stack pattern, as shown in FIG. 4, it has the advantage of increasing the resistance value even when the forming space of the resistive film 300 formed on the substrate 10 is fixed uniformly.

The first and the second resistive part and/or the third resistive part shown in FIGS. 2a to 3c are in a single body when forming the individual resistive film 30, 30′, 30″ in a sputtering manner, and d, the individual width is formed to be the same.

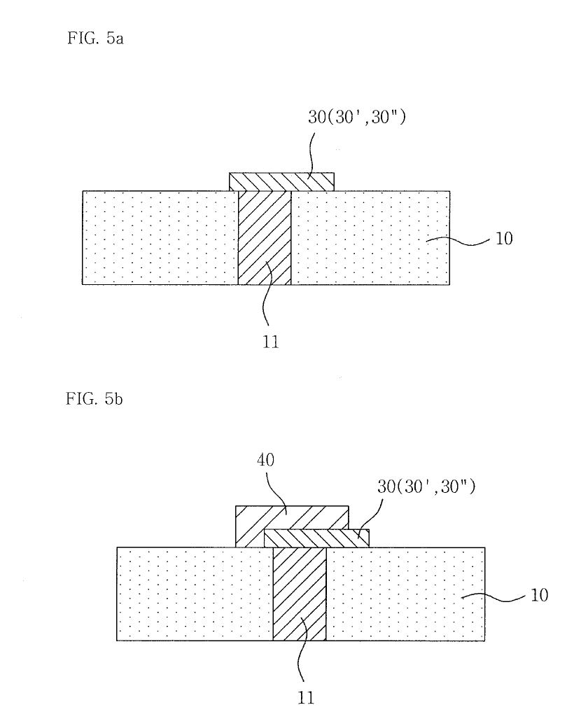

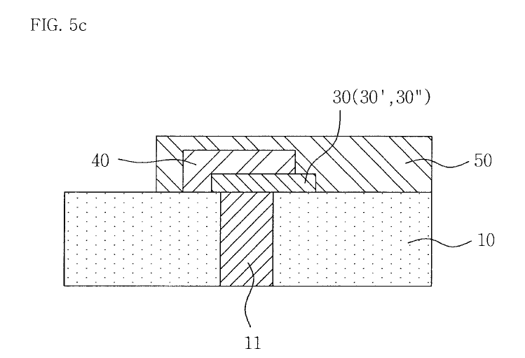

Next, the method for manufacturing the thin film resistance substrate in accordance with the first exemplary embodiment shown in FIG. 2a, will be described in accordance with FIGS. 5a to 5c.

The first exemplary embodiment of this invention prepares the substrate 10 having a via hole 11 filled with a resistor or a via hole filler conductor consisting of a metal selected from Ag, Pd, and Pt.

The substrate 10 may be applied to the substrates for PCB(Printed Circuit Board), semiconductor wafer and MEMS(Micro Electro Mechanical Systems) probe card.

Next, forming the resistive film 30, 30′, 30″ by coating TaN on the substrate 10 having via hole 11 in a sputtering manner, and carrying out the Photolithography process as, for example, the protection film of the resistive film 30, 30′, 30 such as the pattern of the resistive film in FIG. 2 or the resistive film 30, 30′, 30 of the pattern in FIG. 2b, and removing the parts by wet etching excluding the pattern of the resistive film 30, 30′, 30 are performed.

After then, forming the insulating films on the upper part of the substrate 10 as shown in FIG. 5b; and after masking them in a circular-shape by using photoresistor and sputtering a high-k dielectric material selected from Al₂O₃, HfO₂, TiO₂, ZrO₂, Y₂O₃, Ta₂O₅, and La₂O₃ are performed.

The formation of the insulating film 40 is not limited to the sputtering manner. It may he formed by a process selected from ion-assisted physical vapor deposition (PVD) having a high film deposition rate, PVD as e-beam evaporation, pulsed laser deposition (PLD), and aerosol deposition.

After the insulating film 40 is formed, photoresist is removed by a wet etching process, and after the photoresist removing process, the electrode 50 is formed as shown in FIG. 5c.

The electrode 50 is a mixed metal stacked on the substrate 10, the resistive film 30, 30′, 30″ and the insulating film 40; being formed by coating of Ti/Pd/Cu, Ti/Cu, Ti/W/Cu, Al/Cu or Au in a sputtering manner, and by carrying out the Photolithography process as the protection film the same shape as the pattern of the electrode 50 in, for example, FIG. 2b, and by removing the parts excluding the pattern of the electrode 50 through wet etching.

In the process of forming the resistive film 30, 30′, 30″, the insulating film 40 and the electrode 50, the method of ion milling device and dry etching process using Ar, Xe or other reactivity gas, may be used instead of the wet etching process using chemical solution.

In the wet etching process, a metal etching solution may be sprayed optionally to the both sides of the substrate, and the resulting substrate is washed with deionized(D.I)water and then dried.

An undercut phenomenon occurs in the wet etching process. Thus, if an ion milling process capable of reducing the undercut phenomenon is employed, it is possible to form a high precision micro-strip line.

As described above, the thin film resistance substrate 1 is completed by forming the resistive film 30, insulating film 40 and electrode 50.

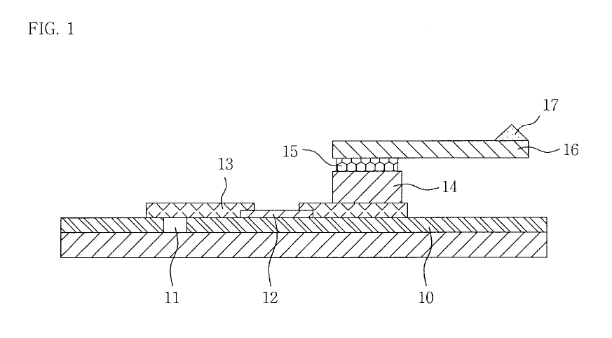

Then, as shown in FIG. 1, a bump pad 14 is formed on the electrode 50 of the thin film resistance substrate 1, and a MEMS probe 16 and a probe tip 17 are sequentially fixed on the bump pad 14 using an adhesive 15, thereby completing a MEMS probe card for a test device for semiconductor IC and others in accordance with the first exemplary embodiment of the present invention.

### Second Exemplary Embodiment

First, the formula 1 of the first exemplary embodiment is still applied to the second exemplary embodiment of the present invention.

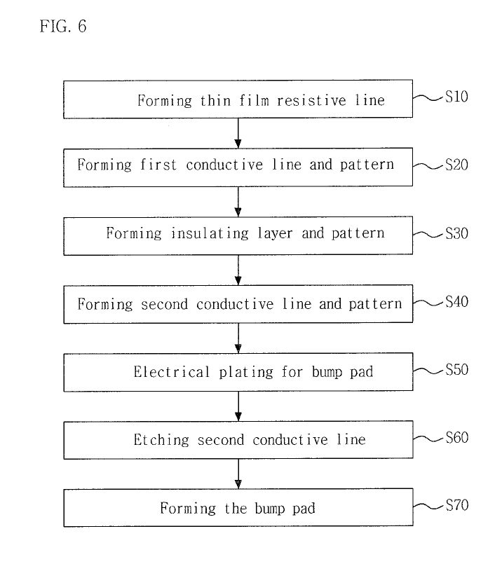

As shown in FIG. 6 to 8, in the exemplary embodiment of the present invention, a substrate 1 having a via hole 2 filled with a via hole filler conductor or resistor is prepared, and then the thin film resistive line 3 is formed on the via hole 2 and the substrate 1(S10).

The via filler conductor 4 may be formed of a metal selected from silver (Ag), palladium (Pd), and platinum (Pt), and preferably Pd or Pt in view of conductivity. The use of TaN is preferable for the material of the thin film resistive line 3.

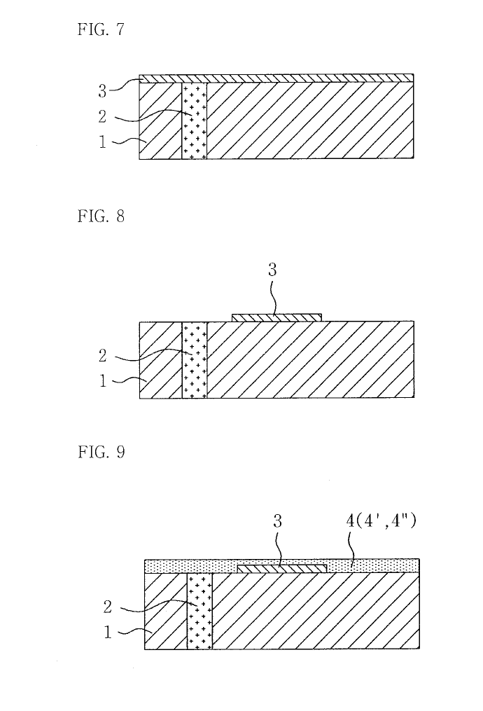

To describe the forming method of the thin film resistive line 3, as shown in FIG. 7, TaN is coated on the whole surface of the substrate 1 in a sputtering manner. Then, a process of laminating dry photoresist (PR) thickly on the surface of the substrate using a laminator is performed. Here, the pressure, temperature, and speed of the laminator may be properly controlled to prevent the formation of pores. If pores are formed in the photoresist, the laminating process may be repeated. It is important that the photoresist has a large thickness, if possible, and preferably a thickness of 120 μm or more.

After completion of the PR lamination process, a UV exposure process is performed, in which UV light is irradiated on the photoresist to form a pattern of the thin film resistive line 3 (see FIG. 8). In this case, a mask pattern is designed so that the irradiated portion is polymerized, and the photoresist is exposed to UV light using a dual exposure system, for example. Here, the important factors are the power of a UV light source and the exposure time. If the power of the UV light source is strong and the exposure time is long, the photoresist is underdeveloped, and thus a pattern larger than a desired pattern is formed. Whereas, if the power of the UV light source is weak and the exposure time is short, the photoresist is overdeveloped and thus a pattern smaller than the desired pattern is formed.

The resistance value of such thin film resistive line 3 is around 100Ω in case of keeping the width being 100 μm uniformly and the length being 200 μm, and around 200Ω in the length of 500 μm, and around 300Ω in the length of 700 μm, and around 400Ω in the length of 900 μm. That is, the desirable resistance value can be obtained by controlling the length of the thin film resistive line 3 in the present invention.

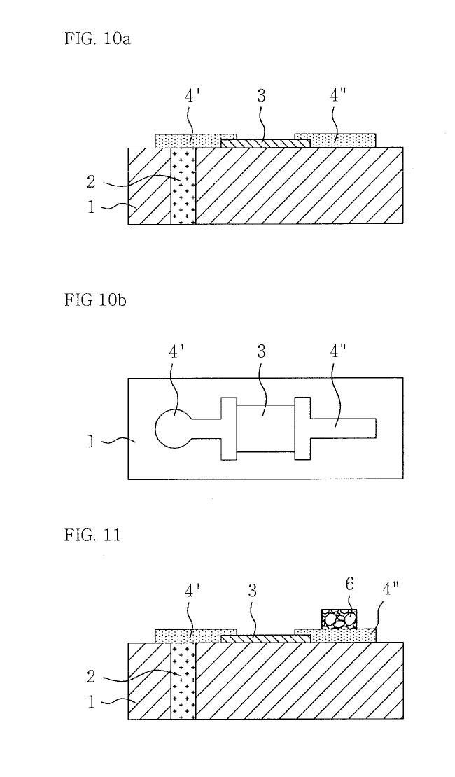

Next, the first conductive line 4 is formed on the substrate 1 and thin film resistive line 3 (S20). A mixed metal of Ti/Pd/Cu is preferable for the material of the first conductive line 4, for which, however, Ti/Cu, Ti/W/Cu, Al/Cu or Au can be used(See FIGS. 9 to 10b).

The forming method of the first conductive line 4 is as follows;

Ti/Pd/Cu is coated, as shown in FIG. 9, on the surface of the substrate 1 and the whole surface of the thin film resistive line 3 in a sputtering manner, then, photoresist(PR) laminated and the pattern of the first conductive line 4 is formed with Photolithography as shown in FIGS. 10a and 10b. After then, the line is connected to the thin film resistive line 3 and forms the two of the first and the second conductive line 4′ and 4″ facing to each other. The first and the second conductive line 4′ and 4″ are formed at the same time.

Next, the insulating layer 5 is formed on the surface of the substrate 1, the thin film resistive line 3 and the first conductive line 4 (S30). The insulating layer 5 is formed with a high-k dielectric material selected from Al₂O₃, HfO₂, TiO₂, ZrO₂, Y₂O₃, Ta₂O₅, and La₂O₃; and Al₂O₃ is preferable in view of cost of material. (See FIG. 11 to 13)

The forming method of the insulating layer 5 is as follows;

As shown in FIG. 11, the photoresist (PR) pattern is formed to form the insulating layer 5 on a part of the second first-conductive line 4″, then the PR pattern 6 is carried out by a lift-off process. The PR pattern 6 may be formed on the first first-conductive line 4′ in case for passing through the via hole 2.

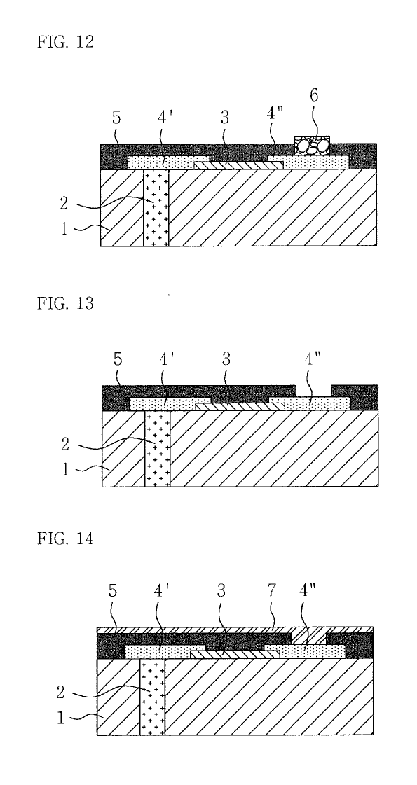

Next, as shown in FIG. 12, an Al₂O₃ layer, a stabilized ZrO₂, or a TiO₂ layer is formed to a thickness of 7 to 10 μm on the surface of the substrate 1, the thin film resistive line 3 and on a part of the first and the second first-conductive line 4′ and 4″ by ion-assisted physical vapor deposition (PVD) having a high film deposition rate, PVD as e-beam evaporation, pulsed laser deposition (PLD), or aerosol deposition.

Then, the insulating layer 5 is, as shown in FIG. 13, formed by removing the PR pattern 6

Next, the second conductive line 7 is formed on the second first-conductive line 4″ and the insulating layer 5 (S40). A mixed metal is used for the material of the second conductive line 7, the same as that of the first conductive line 4.

The second conductive line 7 is, as shown in FIG. 14, formed by coating Ti/Pd/Cu with the insulating layer 5 and the whole surface of the second first-conductive line 4″ exposed from the insulating layer 5 in a sputtering manner.

Next, the electrode 8 for bump pad is formed (S50˜S60).

The forming method of the electrode 8 for bump pad is as follows;

The PR pattern on the second conductive line 7 is formed to form the electrode 8 for bump pad. Then, a mixed metal consisting of Cu, Ni and Au is coated in an electrical plating method with the part in which the PR pattern is not formed. In this case, the Ni is used to prevent inter-diffusion between the Cu layer and the Au layer, and if the Au layer has a thickness of 5 μm or more, preferably 5 to 10 μm, the Ni may be eliminated.

Next, the PR pattern formed in the second conductive line 7 is removed, and the second conductive line 7 is etched on the basis of the electrode 8 for bump pad. Also, as the process of forming the second conductive line 7, the wet etching process using the chemical solution, or the dry etching process using the ion milling device, Ar, Xe or the other reactivity gas may be used.

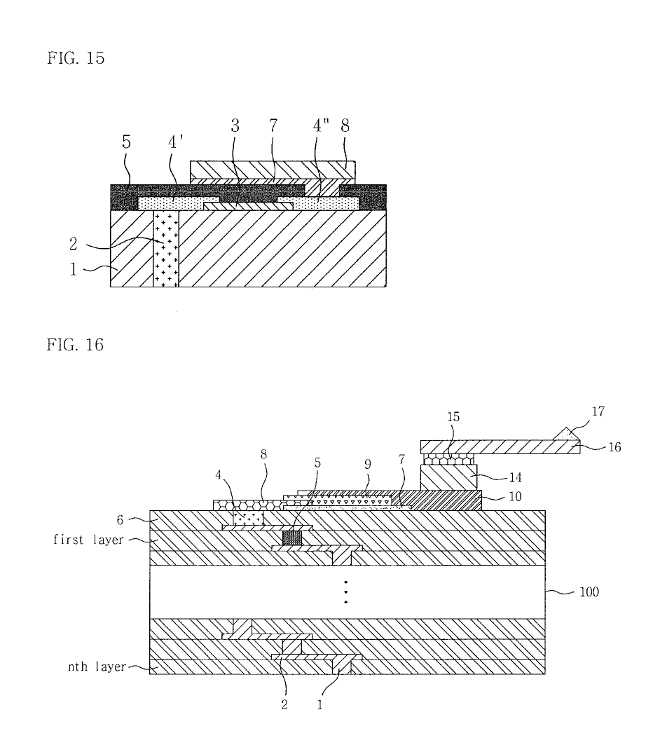

Then, as shown in FIG. 1, a bump pad 14 is formed on the electrode 8 for bump pad shown in FIG. 15 formed in the process described above, a MEMS probe 16 and a probe tip 17 are sequentially fixed on the bump pad 14 using an adhesive 15, thereby completing a MEMS probe card in accordance with the present invention (S70).

### Third Exemplary Embodiment

First, the formula 1 of the first exemplary embodiment is still applied to the third exemplary embodiment of the present invention as the third exemplary embodiment is for the LTCC multilayer having the thin film resistor.

FIG. 16 is a cross sectional view of the MEMS probe card in accordance with the present invention.

As shown in FIG. 16, the micro-electro-mechanical system (MEMS) probe card in the present invention includes; a low-temperature co-fired ceramic (LTCC) multilayer substrate(100) prepared by stacking first to nth LTCC substrates; the upper conductive line 6 prepared on the LTCC multilayer substrate(100) and formed with via hole filled with via hole filler conductor 4; the thin film resistor 7 formed on the upper conductive line 6; the first thin film conductive line 8 formed on the upper conductive line 6; the thin film resistor 7 and via hole filler conductor 4; the insulating film 9 formed on the thin film resistor 7 and the first thin film conductive line 8; and the second thin film conductive line 10 on the upper conductive line 6, the thin film resistor 7 and the insulating film 9.

Meanwhile, the via hole 1 and the conductive line 2 are formed on each of the first to nth layers of the LTCC multilayer substrate 100, and each via hole 1 is filled with via filler conductor which is connected by conductive line 2.

A substrate of any layer of the LTCC multilayer substrate 100, for example, the via hole of the first layer, as shown in FIG. 16, is filled with the thick film resistor 5.

Also, a bump pad 14, an adhesive agent 15, a MEMS probe 16 and a probe tip are formed on the second thin film conductive line 10.

The thin film resistor 7 is desirable to consists of TaN, and the insulating film 9 consists of a high-k dielectric material selected from Al₂O₃, HfO₂, TiO₂, ZrO₂, Y₂O₃, Ta₂O₅, and La₂O₃, however, it may be desirable to consist of Al₂O₃ or TiO₂ in view of the cost.

Also, a mixed metal of Ti/Pd/Cu, Ti/Cu, Ti/W/Cu, Al/Cu or Au is preferable for the first thin film conductive line 8 or the second thin film conductive line 10

The thick film resistor 5 is desirable to consist of a material selected from ruthenium (Ru), ruthenium oxide (e.g. RuO₂, Ru₂O₃), and Ru/ruthenium oxide.

The via filler conductor 4 may consist of a metal selected from Ag, Pd or Pt, however, Pd or Pt is preferable in view of conductivity and as such.

However, the materials for the via filler conductor 4, the thick film resistor 5, the thin film resistor 7, the insulating film 9, the first thin film conductive line 8 and the second thin film conductive line 10 are not limited to those described above, and can be substituted with the materials having the same or similar properties.

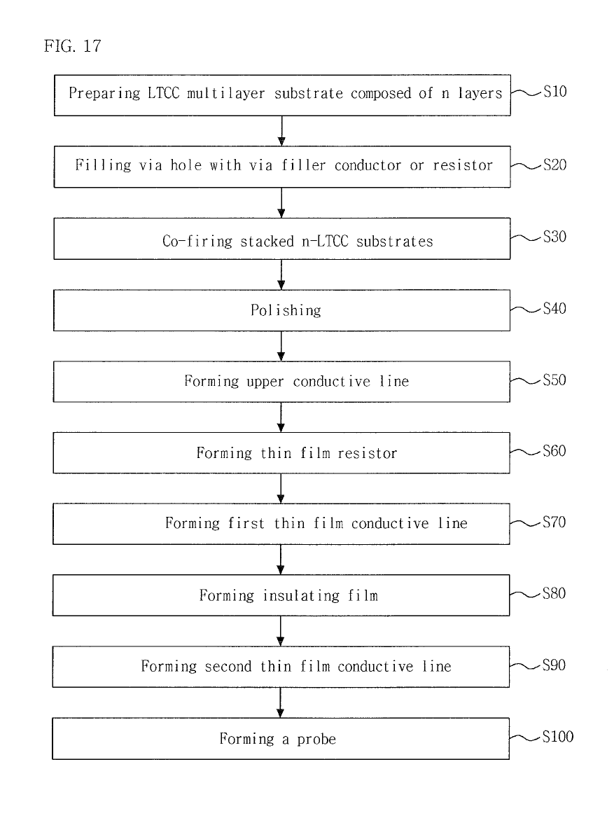

Next, the manufacturing process of the MEMS probe card shown in FIG. 16 will be described in accordance FIGS. 17 to 22.

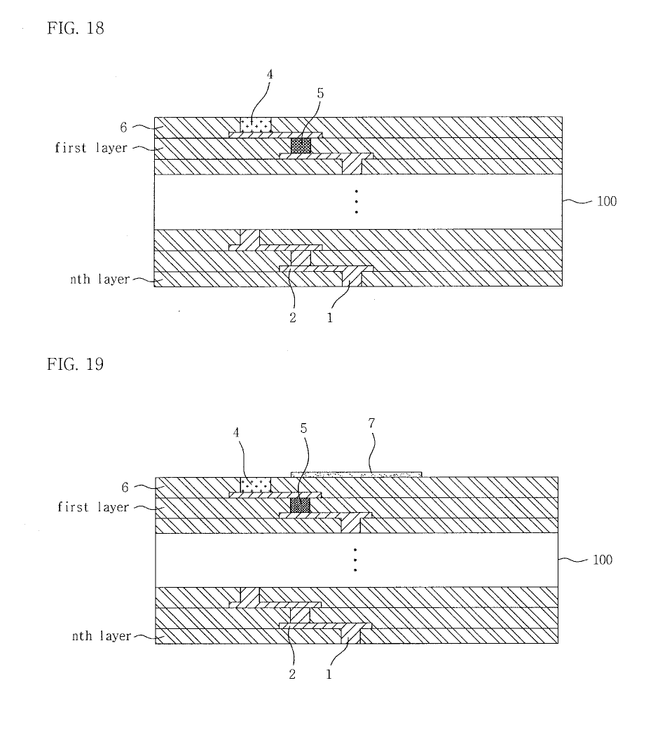

As shown in FIGS. 17 and 18, the exemplary embodiment prepared the LTCC multilayer substrate composed of n layers(S10). Here, The number of layers of the LTCC multilayer substrate 100 may vary according to the substrate design and is preferably 20 to 30 layers according to the test conditions of semiconductor chips. Here, silver (Ag) is mainly used as a material for a metal wiring, and the composition may vary, if necessary. Moreover, ceramic materials used in the LTCC substrate include more than 60 to 70% glass and the remaining alumina. The thickness of each LTCC substrate may vary according to requirements of customers, and is preferably 4 to 7 mm.

Meanwhile, a via hole 1 penetrates each LTCC substrate, and a conductive line 2 is formed on the front or rear surface of each LTCC substrate.

The LTCC multilayer substrate 100 is composed of n green sheets, in each of which a wiring is printed

The via hole 1 formed in each LTCC substrate is filled with a via filler conductor 4, and the via hole 1 formed in the first layer is filled with a thick film resistor 5. The via filler conductor 4 and the thick film resistor 5 are connected to each other by the conductive line 2 (S20).

The thick film resistor 5 is filled within the via hole by means of chemical vapor deposition (CVD, hereinafter) or atomic layer deposition (ALD, hereinafter).

Then, the first and the second to nth LTCC substrates are stacked and co-fired at a temperature of 1,000° C. or less, preferably at a temperature of about 850 to 900° C., to produce an LTCC multilayer substrate 100 (S30).

The surface of the fired LTCC multilayer substrate 100 is rough since the glass and alumina components are bonded to each other, and thus a polishing process is performed (S40).

That is, to form a thin film pattern on the surface of the LTCC multilayer substrate 100, it is required that the surface of the LTCC substrate have a roughness of 1 μm or less, and thus the mechanical polishing process is performed on the surface of the LTCC substrate (S50).

In this case, it is preferable that the LTCC substrate be formed to a thickness greater than a polishing thickness in view of bending of the substrate and that the polishing process be subsequently performed. Generally, the polishing thickness is about 50 to 100 μm, and the surface of the substrate is subjected to thermal annealing according to the uses.

Next, the upper conductive line 6 formed with a via hole is formed on the LTCC multilayer substrate 100, and the via hole 1 formed on the upper conductive line 6 is filled with a via filler conductor 4 (350).

The via filler conductor 4 may be formed of a metal selected from silver (Ag), palladium (Pd), and platinum (Pt), and preferably Pd or Pt in view of conductivity. Although the description has been made with respect to the structure in which only the first LTCC substrate is filled with the via filler conductor 4 as shown in FIG. 18, the present invention is not limited thereto, and the third or fourth LTCC substrate may be filled with the via filler conductor 4.

Then, as shown in FIGS. 17 to 19, the thin film resistor 7 is formed on the upper conductive line 6 having a gap from the via filler conductor 4 (S60). Such thin film resistor 7 is formed of TaN for example, and by means of Photolithography technology, sputtering or aerosol deposition.

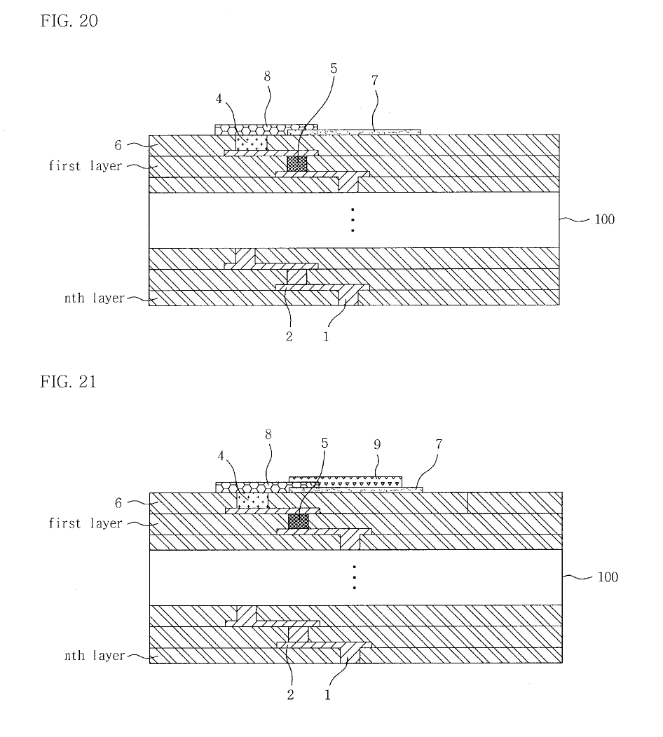

Next, as shown in FIGS. 17 and 20, the first thin film conductive line 8 is formed on the upper conductive line 6, the thin film resistor 7 and the via hole filler conductor 4 (S70).

Here, a Ti or Al layer having a high adhesion strength is deposited to a thickness of 2,000 to 5,000 Å, preferably 3,000 Å, by sputtering to improve the surface adhesion properties between the thin film conductive line 8 and the via filler conductor 4. Then, a palladium (Pd) layer, which serves as a barrier between the Ti or Al layer and a copper (Cu) layer, is deposited to a thickness of 50 to 200 Å, preferably 70 Å on the Ti or Al layer. Finally, a Cu layer, a main conductive line, is deposited to a thickness of 2,500 to 10,000 Å, preferably 9,000 Å or more, on the Pd layer, thereby forming a base metal layer.

As shown in FIGS. 17 and 21, the insulating film 9 of a high-k dielectric material selected from Al₂O₃, HfO₂, TiO₂, ZrO₂, Y₂O₃, Ta₂O₅, and La₂O₃, is formed on the thin film resistor 7 and the first thin film conductive line 8 (S80).

In the forming of the insulating film 9, an Al₂O₃ layer, a stabilized ZrO₂, or a TiO₂ layer is formed to a thickness of 5 to 10 μm by ion-assisted physical vapor deposition (PVD) having a high film deposition rate, PVD as e-beam evaporation, pulsed laser deposition (PLD), or aerosol deposition.

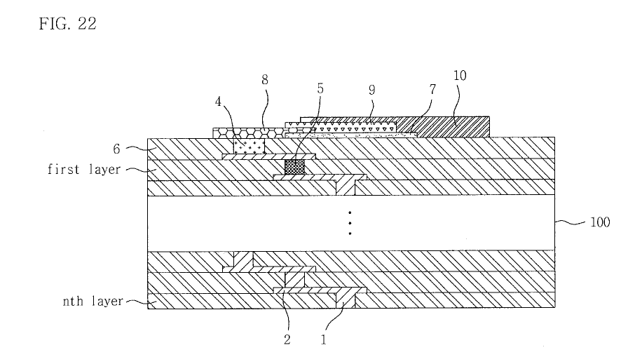

Next, as shown in FIGS. 17 and 22, the second thin film conductive line 10 is formed on the upper conductive line 6, the thin film resistor and the insulating film 9 (S90). The second thin film conductive line 10 may be formed of the same component with the first thin film conductive line 8 and under the same condition.

In the process of forming the insulating film 9 and the first and the second thin film conductive lines 8 and 10, a precise pattern can be formed by means of a wet etching process using chemical solution, or a dry etching process using ion milling device, Ar, Xe or other reactivity gas.

As such, the via resistive conductive line for MEMS probe in accordance with the present invention is completed by the via filler conductor 4, the upper conductive line 6, the thin film resistor 7, the first thin film conductive line 8 and the second thin film conductive line 10.

Then, as shown in FIG. 16, a bump pad 14 is formed on the second thin film conductive line 10, and a MEMS probe 16 and a probe tip 17 are sequentially fixed on the bump pad 14 using an adhesive 15, thereby completing a MEMS probe card for a test device for semiconductor IC and others in accordance with the present invention (S100).

As is apparent from the above description, the present invention provides advantages as described below.

First, according to the present invention, the resistance ratio and resistance value can be easily controlled, and such a device as semiconductor IC tester can cope with the significant change in power.

Second, according to the present invention, the stability of contact pattern between resistive film and electrode can be kept by making the contact area big.

Third, according to the present invention, stable resistance ratio can be obtained within the space at a narrow substrate by forming the second conductive line after coating the insulation layer.

While exemplary embodiments of the present invention have been described and illustrated, it should be understood that various modifications to the described embodiments, which may be evident to those skilled in the art, can be made without departing from the spirit and scope of the present invention as defined by the appended claims.

1. A micro-electro-mechanical system (MEMS) probe card, comprising:
a substrate having a via hole filled with a via hole filler conductor or a resistor;
a resistive film formed on the via hole and the substrate;
an insulating film formed on the resistive film and the substrate; and
an electrode formed on the substrate to cover the resistive film and the insulating film.

2. The MEMS probe card of claim 1, wherein the resistive film is rectangular-shaped and formed with the first resistive part stacked in the part of via hole and the second resistive part stacked on the substrate; and the insulating film is formed to be circular-shaped.

3. The MEMS probe card of claim 1, wherein the end of the first resistive part is formed to be semicircular or circular arc-shaped.

4. The MEMS probe card of claim 2, wherein the resistive film includes further, the third resistive part in series with the second resistive part.

5. The MEMS probe card of claim 4, wherein the third resistive part is formed to be annular-shaped.

6. The MEMS probe card of claim 5, wherein the first and the second resistive parts, or the first, the second and the third resistive parts are formed with one body; each width being the same.

7. The MEMS probe card of claim 1, wherein the resistive film and the insulating film form the multi-layers alternately stacked respectively.

8. A method for manufacturing a micro-electro-mechanical system (MEMS) probe card, the method comprising the steps of:
preparing the substrate filled with a via hole filler conductor or a resistor;
forming a resistive film in the via hole and on the substrate;
forming an insulating film on the resistive film and the substrate; and
forming an electrode on the substrate to cover the resistive film and the insulating film.

9. The method of claim 8, wherein the resistive film and the insulating film form the multi-layers alternately stacked respectively.

10. The MEMS probe card, comprising:
a substrate with a via hole filled with via hole filler conductor or resistor;
a thin film resistive line formed on the surface of the substrate;
the first first-conductive line formed on the surface of the substrate including the surface of the via hole filler conductor, and the second first-conductive line formed on the surface of the substrate facing to the first first-conductive line with the thin film resistive line being between the first first-conductive line and the second first-conductive line;
the insulating layers formed on the substrate, the thin film resistive line and the first and the second first-conductive lines;
the second conductive line formed on the insulating layer and the second first-conductive line exposed out of the insulating layer; and a bump pad and a probe tip fixing onto the second conductive line.

11. The MEMS probe card of claim 10, wherein an electrode for bump pad in a same pattern with the second conductive line on the second conductive line, is formed.

12. A method for manufacturing a micro-electro-mechanical system (MEMS) probe card, the method comprising the steps of:
preparing the substrate having a via hole filled with a via hole filler conductor or a resistor;
forming a thin film resistive line on the surface of the substrate;
forming the first first-conductive line on the surface of the substrate including the surface of the via hole filler conductor, and the second first-conductive line formed on the surface of the substrate facing to the first first-conductive line with the thin film resistive line being between the first first-conductive line and the second first-conductive line;
form a insulating layers on the substrate, the thin film resistive line and the first and the second first-conductive lines;
form a second conductive line on the insulating layer and the second first-conductive line exposed out of the insulating layer; and a bump pad and a probe tip fixing onto the second conductive line.

13. The method of claim 12, wherein the method includes further the step of forming an electrode for bump pad in a same pattern with the second conductive line on the second conductive line.

14. A micro-electro-mechanical system (MEMS) probe card, comprising:
a low-temperature co-fired ceramic (LTCC) multilayer substrate formed by stacking the first to nth substrates and firing the stacked substrates at a temperature of 1,000° C. or less;
the upper conductive line formed with via hole filled with via hole filler conductor, and formed on the LTCC substrate;
the thin film resistor formed on the upper conductive line;
the first thin film conductive line formed on the via hole filler conductor, the upper conductive line and the thin film resistor; and
the insulating film formed on the thin film resistor and the first thin film conductive line.

15. The MEMS probe card of claim 14, wherein the probe card includes further the second thin film conductive line formed on the upper conductive line, the thin film resistor and the thin insulating film.

16. The MEMS probe card of claim 15, wherein one of the via holes formed at the first to nth layers is filled with the thick film resistor.

17. The MEMS probe card of claim 14, wherein the via hole filler conductor consists of a metal selected from Ag, Pd, and Pt.

18. The MEMS probe card of claim 14, wherein the insulating layer consists of Al₂O₃ or TiO₂.

19. The MEMS probe card of claim 14, wherein the first and the second thin film conductive line consist of a mixed metal of Ti, Pd, Cu, or Al, Cu, Au.

20. A method for manufacturing a micro-electro-mechanical system (MEMS) probe card, the method comprising the steps of:
preparing a low-temperature co-fired ceramic (LTCC) multilayer substrate by stacking the first to nth substrates and firing the stacked substrates at a temperature of 1,000° C. or less;
forming the upper conductive line having a via hole on the LTTC multilayer substrate;
filling the via hole with the via hole filler conductor;
forming the thin film resistor on the upper conductive line;
forming the first thin film conductive line on the upper conductive line, thin film resistor and the via hole filler conductor; and
forming the insulating film on the thin film resistor and the first thin film conductive line.

21. The method of claim 20, wherein the method includes further step of forming the second thin film conductive line on the upper conductive line, the thin film resistor and the insulating film after the step of forming the insulating film on the thin film resistor and the first thin film conductive line.

22. The MEMS probe card of claim 21, wherein any one of the via holes formed on the first to nth substrates is filled with the thick film resistive layer at the step of preparing a low-temperature co-fired ceramic (LTCC) multilayer substrate by stacking the first to nth substrates and firing the stacked substrates at a temperature of 1,000° C. or less.

23. The method of claim 22, wherein the insulating layer is formed by a process selected from ion-assisted physical vapor deposition (PVD) having a high film deposition rate, PVD as e-beam evaporation, pulsed laser deposition (PLD), and aerosol deposition.

24. The MEMS probe card of claim 15, wherein the via hole filler conductor consists of a metal selected from Ag, Pd, and Pt.

25. The MEMS probe card of claim 16, wherein the via hole filler conductor consists of a metal selected from Ag, Pd, and Pt.

26. The MEMS probe card of claim 15, wherein the insulating layer consists of Al₂O₃ or TiO₂.

27. The MEMS probe card of claim 16, wherein the insulating layer consists of Al₂O₃ or TiO₂.

28. The MEMS probe card of claim 15, wherein the first and the second thin film conductive line consist of a mixed metal of Ti, Pd, Cu, or Al, Cu, Au.

29. The MEMS probe card of claim 16, wherein the first and the second thin film conductive line consist of a mixed metal of Ti, Pd, Cu, or Al, Cu, Au.

30. The MEMS probe card of claim 3, wherein the resistive film includes further, the third resistive part in series with the second resistive part.
